(19) United States
(12) Patent Application Publication
(10) Pub. No.: US 2017/0186712 A1
(43) Pub. Date: Jun. 29, 2017

(54) CHIP PACKAGE AND METHOD FOR FORMING THE SAME

(71) Applicant: XINTEC INC., Taoyuan City (TW)

(72) Inventors: Chia-Lun SHEN, Taoyuan City (TW); Po-Shen LIN, New Taipei City (TW); Ang CHAN, Taipei City (TW)

(21) Appl. No.: 15/393,170

(22) Filed: Dec. 28, 2016

Related U.S. Application Data
(60) Provisional application No. 62/272,560, filed on Dec. 29, 2015.

(51) Int. Cl. H01L 23/00; H01L 21/768; H01L 21/78; H01L 23/31

(52) U.S. Cl. CPC H01L 24/02; H01L 23/3185; H01L 24/13; H01L 24/94; H01L 23/3114; H01L 23/3121; H01L 21/76898; H01L 21/78; H01L 2224/02371; H01L 2224/02381; H01L 2224/02311; H01L 2224/12105; H01L 2224/13024; H01L 2924/12041; H01L 2924/12043; H01L 27/14687

(57) ABSTRACT

A chip package including a substrate is provided. The substrate includes a front surface, a back surface, and a side surface. A redistribution layer is disposed on the back surface and is electrically connected to a sensing or device region in the substrate. A protection layer covers the redistribution layer and extends onto the side surface. A cover plate is disposed on the front surface and laterally protrudes from the protection layer on the side surface. The cover plate includes a first surface facing the front surface and a second surface facing away from the front surface. A bottom portion of the cover plate broadens from the first surface towards the second surface. A method of forming the chip package is also provided.

### CROSS REFERENCE TO RELATED APPLICATIONS

This application claims the benefit of U.S. Provisional Application No. 62/272,560 filed on Dec. 29, 2015, the entirety of which is incorporated by reference herein.

### BACKGROUND OF THE INVENTION

Field of the Invention

The invention relates to chip package technology, and in particular to a chip package using wafer-level package technology and methods for forming the same.

Description of the Related Art

In general, the wafer-level package process involves the wafer with chips being diced to obtain individual packages after the packaging step has been accomplished during the wafer stage. The chip package not only protects the chip therein from ambient contamination, but it also provides electrical connections between the interior electronic devices and the exterior circuits.

However, when a sawing process is performed on the wafer, layers formed in and/or on the wafer may easily become cracked and damaged due to the cutting shift during the sawing process. Moreover, non-uniform recesses and heaves may be caused at positions that are sawed, thereby obtaining chip packages with poor quality and reliability. Moreover, the size of the scribe lines of the wafer depends on the size of the dicing saw, so the number of chip packages obtained by dicing a single wafer is limited. Furthermore, the sawing process needs a long time for processing because the speed of the sawing process is slow. Therefore, it is difficult to further reduce the manufacturing cost and time.

Accordingly, there exists a need for seeking a novel chip package and methods for forming the same capable of eliminating or mitigating the aforementioned problems.

### BRIEF SUMMARY OF THE INVENTION

An embodiment of the invention provides a chip package which includes a substrate having a front surface, a back surface, and a side surface. A redistribution layer is disposed on the back surface and is electrically connected to a sensing or device region in the substrate. A protection layer covers the redistribution layer and extends onto the side surface. A cover plate is disposed on the front surface and laterally protrudes from the protection layer on the side surface. The cover plate has a first surface facing the front surface and a second surface facing away from the front surface. A bottom portion of the cover plate broadens from the first surface towards the second surface.

An embodiment of the invention provides a method for forming a chip package which includes providing a substrate. The substrate has a front surface, a back surface, and a side surface. A redistribution layer is formed on the back surface. The redistribution layer is electrically connected to a sensing or device region in the substrate. A protection layer is formed to cover the redistribution layer and extend onto the side surface. A cover plate is formed on the front surface. The cover plate laterally protrudes from the protection layer on the side surface. The cover plate has a first surface facing the front surface and a second surface facing away from the front surface. A bottom portion of the cover plate broadens from the first surface towards the second surface.

### BRIEF DESCRIPTION OF THE DRAWINGS

The present invention can be more fully understood by reading the subsequent detailed description and examples with references made to the accompanying drawings, wherein:

FIGS. 1A to 1H are cross-sectional views of an exemplary embodiment of a method for forming a chip package according to the invention.

FIG. 2 is a cross-sectional view of an exemplary embodiment of a portion of a chip package according to the invention.

FIG. 3 is a plan view of an exemplary embodiment of a chip package according to the invention.

FIGS. 4A to 4E are cross-sectional views of another exemplary embodiment of a method for forming a chip package according to the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Furthermore, when a first material layer is referred to as being on or overlying a second material layer, the first material layer may be in direct contact with the second material layer, or spaced apart from the second material layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multilayer integrated circuit devices by stacking a plurality of wafers having integrated circuits.

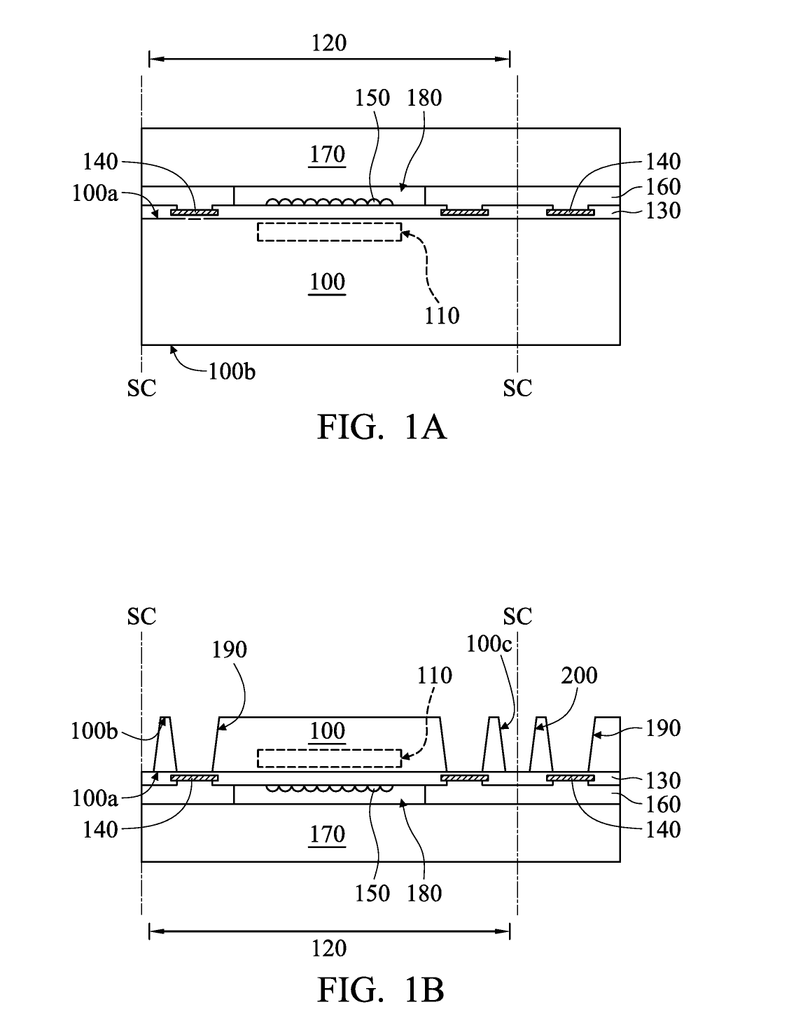

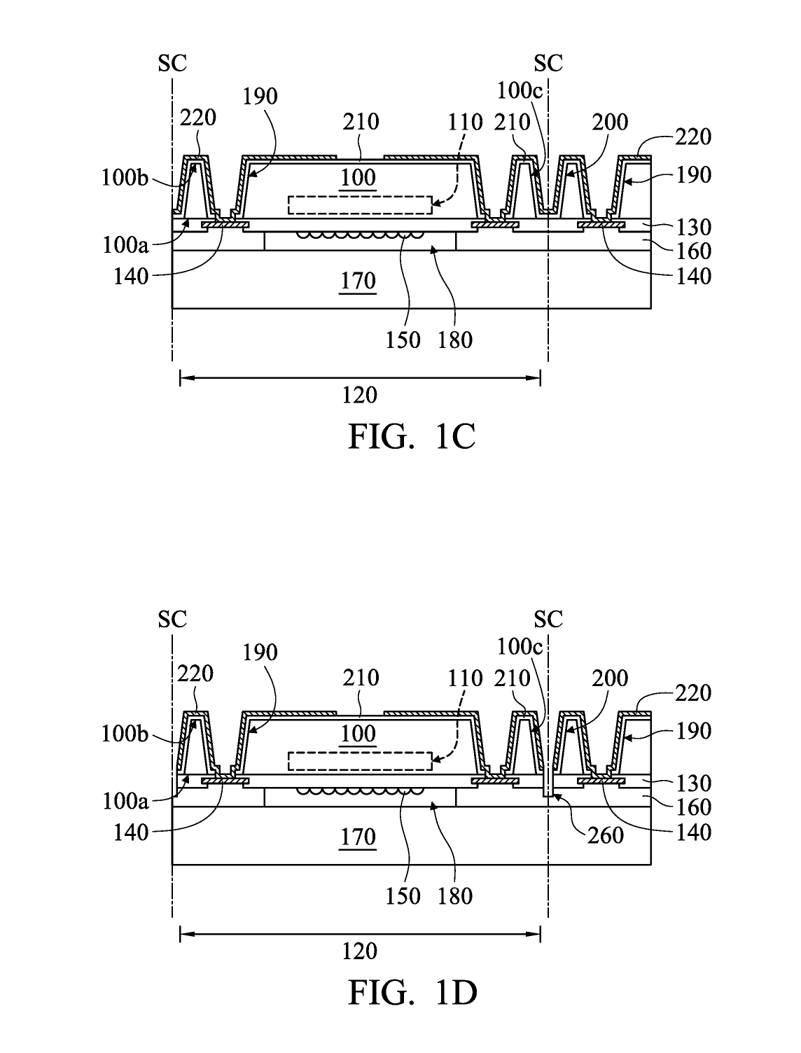

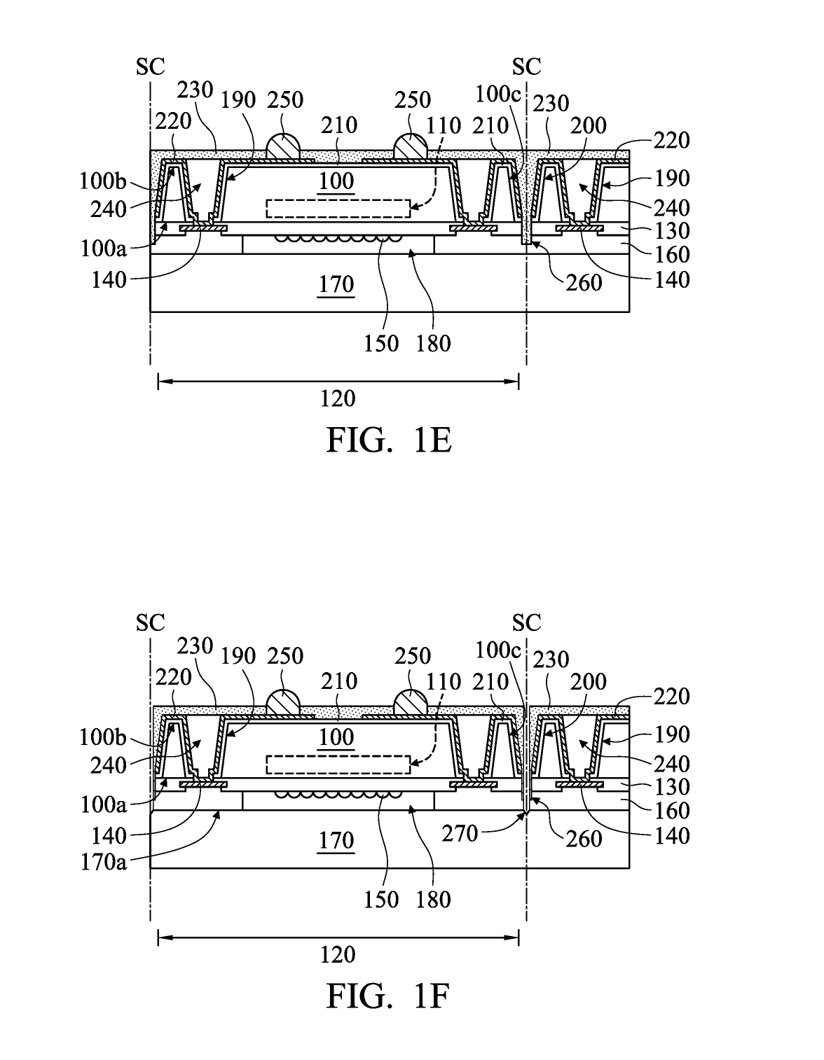

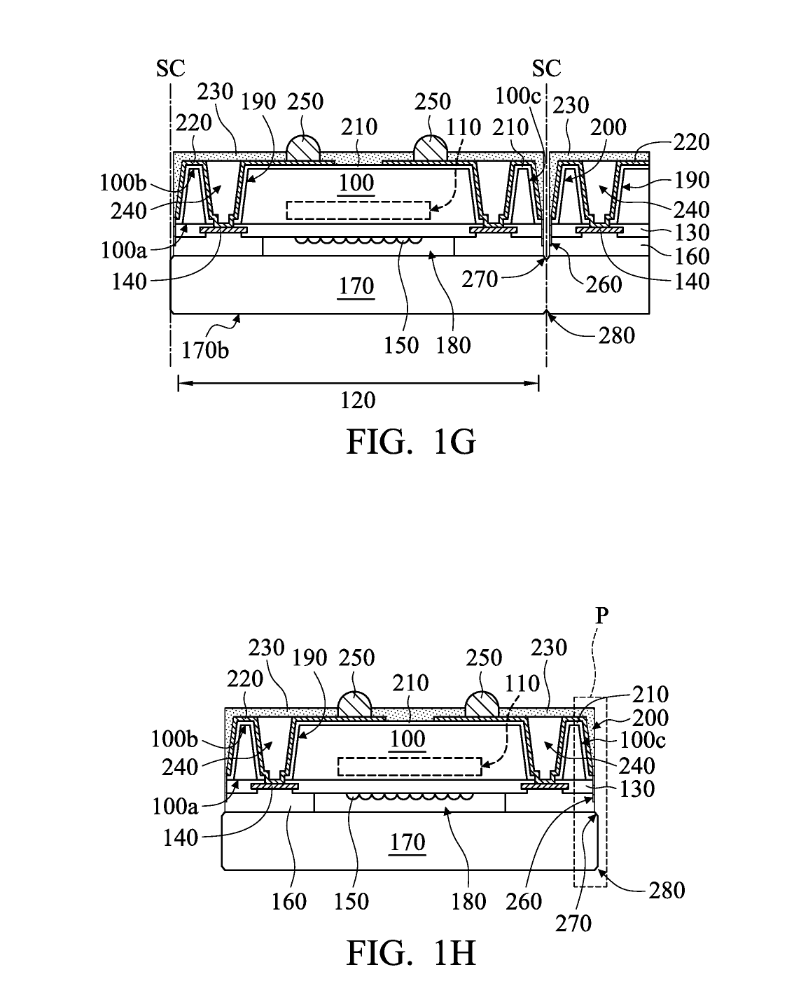

FIGS. 1A to 1H illustrate an exemplary embodiment of a method for forming a chip package according to the invention, in which FIGS. 1A to 1H are cross-sectional views of an exemplary embodiment of a method for forming a chip package according to the invention.

Refer to FIG. 1A, a substrate 100 having a front surface 100a and a back surface 100b and including chip regions 120 is provided. To simplify the diagram, only an entire chip region 120 and a portion of an adjacent chip region are depicted herein. In some embodiments, the substrate 100 may be a silicon substrate or another semiconductor substrate. In some embodiments, the substrate 100 is a silicon wafer for facilitating the wafer-level packaging process.

The front surface 100a of the substrate 100 may have an insulating layer 130. In general, the insulating layer 130 may be formed of an interlayer dielectric (ILD) layer, an inter-metal dielectric (IMD) layer, and a passivation layer covering thereon. To simplify the diagram, only a single insulating layer 130 is depicted herein. In some embodiments, the insulating layer 130 may comprise an inorganic material, such as silicon oxide, silicon nitride, silicon oxynitride, metal oxide, or a combination thereof, or another suitable insulating material.

In some embodiments, the insulating layer 130 of each chip region 120 includes one or more conductive pads 140 therein. In some embodiments, the conductive pad 140 may be formed of a single conductive layer or multiple conductive layers. To simplify the diagram, only a single conductive layer is depicted herein as an example. In some embodiments, the insulating layer 130 of each chip region 120 has one or more openings to expose corresponding conductive pads 140.

In some embodiments, each chip region 120 includes a sensing or device region 110. The sensing or device region 110 may be adjacent to the insulating layer 130 and the front surface 100a of the substrate 100, and is electrically connected to the conductive pad 140 via an interconnect structure (not shown). The sensing or device region 110 includes sensing devices therein. In some embodiments, the sensing or device region 110 includes light-sensing devices or other suitable opto-electronic devices. In other embodiments, the sensing or device region 110 may include a device that is configured to sense biometrics (e.g., fingerprint recognition devices), a device that is configured to sense environmental characteristics (e.g., temperature-sensing element, humidity-sensing element, pressure-sensing element, capacitance-sensing element), or another suitable sensing element.

In some embodiments, the front-end process (e.g., formation of the sensing or device region 110 in the substrate 100) and the back-end process (e.g., formation of the insulating layer 130, the interconnect structure, and the conductive pads 140 over the substrate 100) for a semiconductor device may be successively performed to provide the structure previously mentioned. In other words, the following method for forming a chip package is used for performing package processes on the substrate after the back-end process is completed.

In some embodiments, each chip region 120 includes an optical component 150 therein and the optical component 150 is disposed on the front surface 100a of the substrate 100 and corresponds to the sensing or device region 110. In some embodiments, the optical component 150 may comprise a microlens array, a color filter, or a combination thereof or another suitable optical component.

Afterwards, a spacer layer (or referred to as dam) 160 is formed over a cover plate 170. The cover plate 170 is bonded onto the front surface 100a of the substrate 100 via the spacer layer 160 which defines a cavity 180 between the substrate 100 in each chip region 120 and the cover plate 170, such that the optical component 150 is in the cavity 180 and is protected by the cover plate 170. In other embodiments, the spacer layer 160 may first be formed on the front surface 100a of the substrate 100, and then the cover plate 170 is bonded onto the substrate 100. In some embodiments, the cover plate 170 may comprise glass, aluminum nitride (AlN), or another suitable transparent material. In some embodiments, the cover plate 170 has a thickness in a range of about 700 μm or has another suitable thickness.

In some embodiments, the spacer layer 160 is substantially unabsorbed moisture. In some embodiments, the spacer layer 160 may not have a stickiness, and therefore the cover plate 170 may be adhered onto the substrate 100 via an additional adhesive glue. In some embodiments, the spacer layer 160 may have a stickiness, and therefore the cover plate 170 may be adhered onto the substrate 100 via the spacer layer 160. As a result, the spacer layer 160 may not be in contact with any adhesive glue, so as to ensure that the spacer layer 160 does not shift from its position due to the adhesive glue. Moreover, since there is no need to use the adhesive glue, the contamination of the optical component 170 due to overflow of the adhesive glue can be eliminated.

In some embodiments, the spacer layer 160 may be formed by a deposition process (such as a spin coating process, a physical vapor deposition process, a chemical vapor deposition process, or another suitable process). In some embodiments, the spacer layer 160 may comprise an epoxy, an inorganic material (e.g., silicon oxide, silicon nitride, silicon oxynitride, metal oxide, or a combination thereof), an organic polymer material (e.g., polyimide, butylcyclobutene (BCB), parylene, polynaphthalenes, fluorocarbons, acrylates), or another suitable insulating material. Alternatively, the spacer layer 160 may comprise a photoresist material and therefore it can be patterned through exposure and development processes, so as to expose the optical component 150.

Refer to FIG. 1B, a thinning process (e.g., an etching process, a milling process, grinding process, or a polishing process) is performed on the back surface 100b of the substrate 100 using the cover plate 170 as a carrier substrate, thereby reducing the thickness of the substrate 100.

Afterwards, first openings 190 and a second opening 200 are simultaneously formed in the substrate 100 of each chip region 120 by a lithography process and an etching process (e.g., a dry etching process, a wet etching process, a plasma etching process, a reactive ion etching process, or another suitable process). The first openings 190 and the second opening 200 expose the insulating layer 130 from the back surface 100b of the substrate 100. In other embodiments, the second opening 200 and the first openings 190 are respectively formed by a notching process and the lithography and etching processes.

In some embodiments, the first openings 190 correspond to the conductive pads 140 and pass through the substrate 100. The diameter of the first openings 190 adjacent to the front surface 100a is less than that adjacent to the back surface 100b, so that the first openings 190 have a tapered side surface, thereby reducing the difficulty of the process in subsequently forming film(s) in the first openings 190 and increasing the reliability. For example, since the diameter of the first openings 190 adjacent to the front surface 100a is less than that adjacent to the back surface 100b, the subsequently formed film(s) (e.g., the subsequently formed insulating layer 210 and redistribution layer 220) in the first openings 190 may easily be deposited on the corners between the first openings 190 and the insulating layer 130, so as to prevent adverse effects on the electrical connection path or prevent leakage.

In some embodiments, the second opening 200 extend along the scribe line SC between adjacent chip regions 120 and pass through the substrate 100, so that the substrate 100 of chip regions 120 are separated from each other. The diameter of the second opening 200 adjacent to the front surface 100a is less than that adjacent to the back surface 100b, so that the second opening 200 has a tapered side surface. Namely, the substrate 100 of each chip region 120 has a tapered side surface 100c.

In some embodiments, the first openings 190 in two adjacent chip regions 120 are arranged at intervals along the second opening 200. The first openings 190 and the second opening 200 are spaced apart and entirely isolated from each other via a portion of the substrate 100 (e.g., a sidewall portion). In some embodiments, the second opening 200 extends along the chip region 120 and surrounds the first openings 190. In some embodiments, the first openings 190 are connected to the second opening 200. For example, the portion of each first opening 190 that is adjacent to the back surface 100b and the portion of the second opening 200 that is adjacent to the back surface 100b are connected to each other, such that the substrate 100 has a sidewall portion with a height lower than the back surface 100b. In other words, such a sidewall portion has a thickness that is less than that of the substrate 100. The first openings 190 and the second opening 200 are connected to each other, rather than entirely isolated from each other via a portion of the substrate 100, so as to prevent the stress from accumulating in the substrate 100 between the first openings 190 and the second opening 200. Moreover, the stress can be mitigated or eliminated via the second opening 200, thereby preventing the sidewall portion of the substrate 100 from cracking.

Refer to FIG. 1C, an insulating layer 210 is formed over the back surface 100b of the substrate 100 via a deposition process (such as a spin coating process, a physical vapor deposition process, a chemical vapor deposition process, or another suitable process). The insulating layer 210 is conformally deposited on the sidewalls and the bottoms of the first openings 190 and the second openings 200. In some embodiments, the insulating layer 210 may comprise an epoxy, an inorganic material (e.g., silicon oxide, silicon nitride, silicon oxynitride, metal oxide, or a combination thereof), an organic polymer material (e.g., polyimide, butylcyclobutene, parylene, polynaphthalenes, fluorocarbons, acrylates), or another suitable insulating material.

Afterwards, the insulating layer 210 and the underlying insulating layer 130 at the bottom of each first opening 190 are removed, so that the first openings 190 extend into the insulating layer 130 to expose the corresponding conductive pads 140.

Thereafter, a patterned redistribution layer 220 is formed over the insulating layer 210 via a deposition process (such as a spin coating process, a physical vapor deposition process, a chemical vapor deposition process, or another suitable process), a lithography process, and an etching process. The redistribution layer 220 conformally extends to the sidewalls and the bottoms of the first openings 190 and the second opening 200. Namely, the redistribution layer 220 conformally extends to the side surface 100c of the substrate 100.

In the embodiment, the redistribution layer 220 is electrically isolated from the substrate via the insulating layer 210 and directly or indirectly and electrically contacts the exposed conductive pads 140 through the first openings 190. Therefore, the redistribution layer 220 in each first opening 190 is also referred to as a through silicon vias (TSV). In some embodiments, the redistribution layer 220 may comprise aluminum, copper, gold, platinum, nickel, tin, a combination thereof, a conducting polymer material, a conducting ceramic material (e.g., indium tin oxide or indium zinc oxide), or other suitable conducting materials.

Refer to FIG. 1D, a recess 260 is formed along the scribe line SC and connected to the second opening 200. The recess 260 passes through the redistribution layer 220 and the insulating layer 210 in the second opening 200 and the insulating layer 130 to extend further into the spacer layer 160. The recess 160 cuts off the redistribution layer 220, so that the redistribution layer 220 between the adjacent chip regions 120 is separated. In other embodiments, the recess 260 may pass through the spacer layer 160. In some embodiments, the recess 260 is formed by a dicing process and not limited thereto. For example, the redistribution layer 220, the insulating layer 210, the insulating layer 130, and the spacing layer 160 are cut by a dicing saw to form the recess 260.

Refer to FIG. 1E, a protection layer 230 may be formed on the back surface 100b and the side surface 100c of the substrate 100 by a deposition process, so as to cover the redistribution layer 220. In some embodiments, the protection layer 230 fully fills the second opening 200. The protection layer 230 further fills the recess 260 and cover the end of the redistribution layer 220. The protection 230 also covers the end of the insulating layer 210, the side surface of the insulating layer 130, and a portion of the side surface of the spacer layer 160.

In some embodiments, the protection layer 130 does not fill the first openings 190, so a hole 240 is formed between the redistribution layer 220 and the protection layer 230 in the first opening 190. Since the protection layer 230 partially fills the first opening 190 and leaves the hole 240, the hole 240 can be a buffer between the protection layer 230 and the redistribution layer 220 in thermal cycles induced in subsequent processes. Undesirable stress, which is induced between the protection layer 230 and the redistribution layer 220 as a result of a mismatch of thermal expansion coefficients, is reduced. The redistribution layer 220 is prevented from being excessively pulled by the protection layer 230 when external temperature or pressure dramatically changes. As a result, problems such as peeling or disconnection of the redistribution layer 220, which is close to the conductive pad structure, are avoidable. In other embodiments, the protection layer 230 may partially fill the first opening 190 or fully fill the first opening 190.

In some embodiments, the protection layer 230 may comprise epoxy resin, solder mask, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates), or another suitable insulating material.

Afterwards, openings may be formed in the protection layer 230 on the back surface 100b of the substrate 100 by lithography and etching processes so as to expose portions of the redistribution layer 220. Subsequently, conductive structures 250 (such as solder balls, bumps or conductive pillars) may be filled in the openings of the protection layer 230 by an electroplating process, a screen printing process or another suitable process to electrically connect to the exposed redistribution layer 220. In one embodiment, the conductive structures 250 may comprise tin, lead, copper, gold, nickel or a combination thereof.

Refer to FIG. 1F, a recess 270 is formed along the scribe line SC. The recess 270 passes through the second opening 200 and the recess 260 in the protection layer 230 and passes through the spacer layer 160 to extend further into the cover plate 170. The recess 270 extends from a first surface 170a of the cover plate 170 that faces the front surface 100a toward inside of the cover plate 170. In some embodiments, the recess 270 in the cover plate 170 surrounds the protection layer 230 and the conductive pad structures 250 as viewed from the top. In some embodiments, the recess 270 in the cover plate 170 has a triangular cross-sectional view profile, but the recess 270 is not limited thereto and may have a cross-sectional view profile with another shape. In some embodiments, the recess 270 is formed by a laser drilling process or another suitable process.

In some embodiments, the recess 270 has a width less than that of the recess 260. The recess 270 has a depth greater than that of the recess 260. After the recess 270 is formed, the protection layer 230 still covers the end of the redistribution layer 220, the end of the insulating layer 210, the side surface of the insulating layer 130, and a portion of side surface of the spacer layer 160.

Refer to FIG. 1G, a notch 280 is formed in the cover plate 170 and extends from a second surface 170b of the cover plate 170 that faces away from the front surface 100a. In some embodiments, the notch 280 is substantially aligned with the recess 270. In some embodiments, the notch 280 has a triangular cross-sectional view, but the notch 280 is not limited thereto and may have a cross-sectional view with another shape. In some embodiments, the notch 280 is formed using a scribing technique or another suitable method. For example, the second surface 170b of the cover plate 170 is scribed along the scribe line SC by a cutter wheel or another suitable scriber to form the notch 280.

Afterwards, the cover plate 170 is vertically cut off along the recess 270 and the notch 280 by a breaking cut technique using a breaker or another suitable method, so as to separate the cover plate 170 of each chip region 120, thereby forming individual chip packages, as shown in FIG. 1H.

According to foregoing embodiments, the recess 270 is formed on the first surface 170a of the cover plate 270 and the notch 280 is formed on the second surface 170b of the cover plate 170, and the cover plate 170 of each chip region 120 is separated by the breaking cut technique to form an individual chip package. As a result, the cover plate 170 can be uniformly cut off directly along the recess 270 and the notch 280, so as to form a flattening side surface. The recess 270 increases the accuracy and precision of the breaking cut technique that are advantageous to separate the cover plate 170. For example, non-uniform recesses and heaves at the side surface of the cover plate 170 can be prevented, and chipping of the surface of the cover plate 170 is also prevented.

Moreover, the recess 260 is pre-formed along the scribe line SC prior to formation of the protection layer 230, and the protection layer 230 subsequently fills the recess 260. Next, the protection layer 230 of each chip region 120 is separated by forming the recess 270 (e.g., performing a laser drilling process), in which the size of the recess 270 is less than that of the recess 260. As a result, the protection layer 230 can be prevented from being seriously cracked and damaged, thereby ensuring that the side surface of the separated chip package is capable of being protected very well by the protection layer 230. Moreover, layers in the chip package (e.g., the redistribution layer 220, the insulating layer 210, the insulating layer 130, and the spacer layer 160) can be protected from damage during the separation mentioned above, thereby increasing the quality and reliability of the chip package.

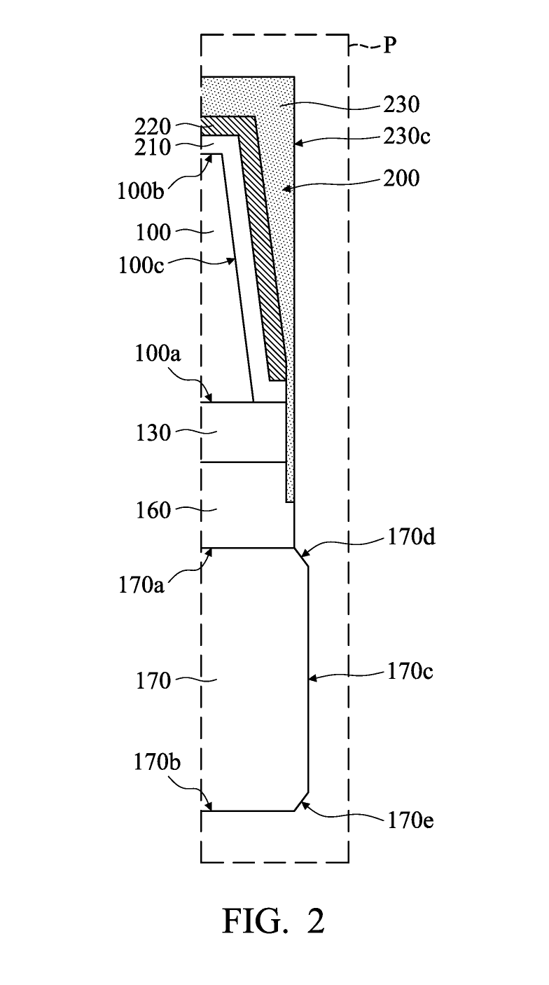

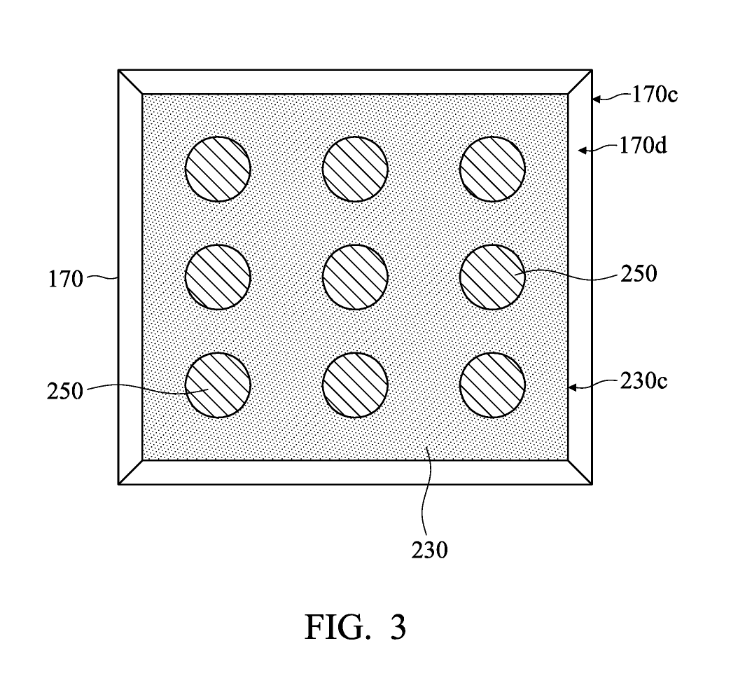

Refer to FIGS. 1H, 2, and 3, in which the FIG. 2 is a cross-sectional view of a portion of a chip package shown in FIG. 1H, and FIG. 3 is a plan view of an exemplary embodiment of a chip package according to the invention. In the embodiments mentioned above, front side illumination (FSI) sensor devices are used as examples. However, these embodiments are not limited to any specific application, and back side illumination (BSI) sensor devices may be also used for these embodiments.

In the chip package that is formed by the method mentioned above, the redistribution layer 220 that is electrically connected to the sensing or device region 110 and the conductive pads 140 is on the back surface 100b of the substrate 100 and further extends to the side surface 100c. The protection layer 230 not only covers the redistribution layer 220 on the back surface 100b, but also covers the redistribution layer 220 on the side surface 100c and further extends beyond the front surface 100a of the substrate 100. The cover plate 170 is on the front surface 100a of the substrate 100 and laterally protrudes from the protection layer 230 on the side surface 100c. In other words, the width of the cover plate 170 is greater than the width of the substrate 100 and also greater than the width of the protection layer 230. Moreover, the side surface of the cover plate 170 and the side surface of the protection layer 230 are not coplanar.

As shown in FIG. 2, the cover plate 170 has a first surface 170a facing the front surface 100a, a second surface 170b facing away from the front surface 100a, and a side surface 170c. Moreover, a recess 270 is formed so that the bottom portion of the cover plate 170 has a side surface 170d that is adjacent to the first surface 170a and the side surface 170c. Also, a notch 280 is formed so that the top portion of the cover plate 170 has a side surface 170e that is adjacent to the second surface 170b and the side surface 170c. In some embodiments, the side surface 170c is adjacent to the bottom portion and the top portion of the cover plate 170, and is substantially vertical to the first surface 170a and/or the second surface 170b. Moreover, the side surface 170d is tilted to the first surface 170a and/or the second surface 170b, the side surface 170e is tilted to the first surface 170a and/or the second surface 170b, and the side surface 170d and/or the side surface 170e is/are tilted to the side surface 170c. In some embodiments, a normal vector of the side surface 170d is substantially parallel to the side surface 170e.

As shown in FIGS. 1H and 2, the recess 270 is formed so that the bottom portion of the cover plate 170 broadens from the first surface 170a toward the second surface 170b. Also, the notch 280 is formed so that the top portion of the cover plate 170 broadens from the second surface 170b toward the first surface 170a. In some embodiments, the bottom portion of the cover plate 170 gradually broadens from the first surface 170a toward the second surface 170b. Moreover, the top portion of the cover plate 170 gradually broadens from the second surface 170b toward the first surface 170a. In some embodiments, the broadening gradient of the bottom portion of the cover plate 170 is substantially equal to the broadening gradient of the top portion of the cover plate 170. Moreover, the middle portion that is interposed between the bottom portion and the top portion of the cover plate 170 has a substantially uniform and constant thickness. Namely, the side surface 170c of the middle portion is a flat surface.

As shown in FIGS. 1H and 2, in some embodiments, the protection layer 230 on the side surface 100c has a flat side surface 230c. In some embodiments, the side surface 230c is substantially vertical to the first surface 170a and/or the second surface 170b, and the side surface 230c is substantially parallel to the side surface 170c, as shown in FIG. 3. In some embodiments, the side surface 170d is tilted to the side surface 230c and the side surface 170e is tilted to the side surface 230c. Moreover, in some embodiments, an edge of the first surface 170a is substantially aligned with the side surface 230c and an edge of the second surface 170b is substantially aligned with the side surface 230c. In other words, an edge of the side surface 170d is substantially aligned with the side surface 230c and an edge of the side surface 170e is substantially aligned with the side surface 230c. In some embodiments, the side surface 170d surrounds the protection layer 230, as viewed from the top, as shown in FIG. 3.

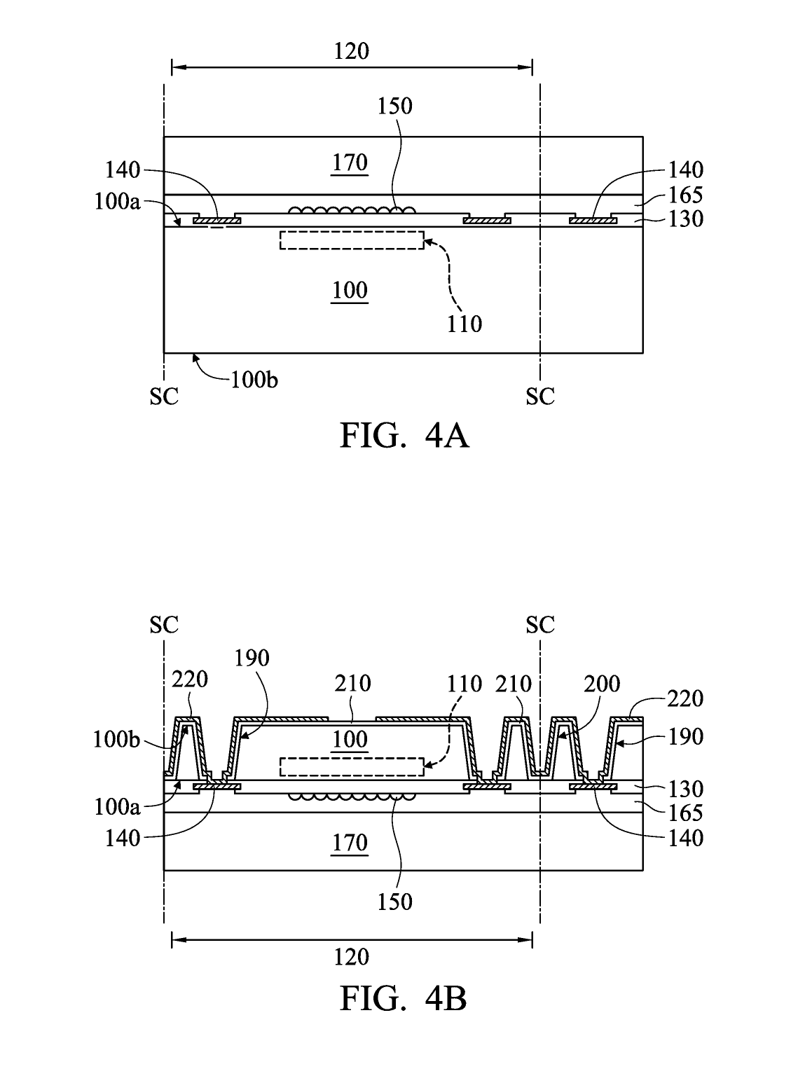

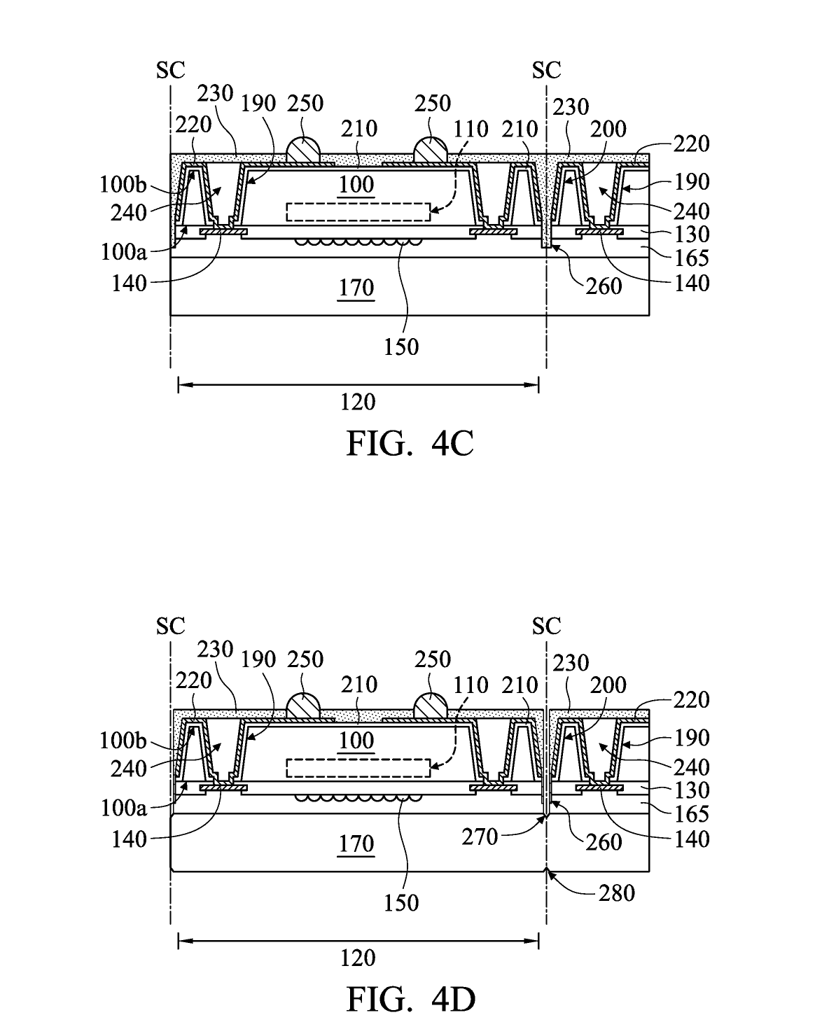

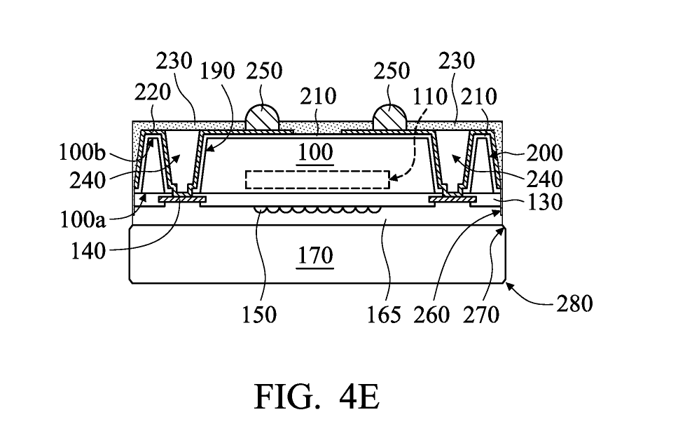

Refer FIGS. 4A to 4E, cross-sectional views of another exemplary embodiment of a method for forming a chip package according to the invention are illustrated. FIGS. 4A to 4E are cross-sectional views of another exemplary embodiment of a method for forming a chip package according to the invention. Elements in FIGS. 4A to 4E that are the same as those in FIGS. 1A to 1H are labeled with the same reference numbers as in FIGS. 1A to 1H and are not described again for brevity.

Refer to FIG. 4A, a substrate 100 is provided by a step that is the same or similar to that shown in FIG. 1A, in which a front surface 100a of the substrate 100 in each chip region 120 has an insulating layer 130 thereon, and the insulating layer 130 includes an optical component 150. Next, a cover plate 170 may be bonded onto the substrate 100 via an adhesive layer 165. In some embodiments, the adhesive layer 165 that is formed between the cover plate 170 and the substrate 100 entirely covers the front surface 100a of the substrate 100, so that the optical component 150, the insulating layer 130, the conductive pads 140, and the sensing or device region 110 are also covered by the adhesive layer 165. In some embodiments, the adhesive layer 165 is a double-sided glue material or another suitable adhesive material.

Refer to FIG. 4B, a thinning process may be performed on the substrate 100 using a step that is the same or similar to that shown in FIG. 1B, so as to form first openings 190 and a second opening 200. Afterwards, an insulating layer 210 and a redistribution layer 220 are formed on a back surface 100b of the substrate 100 in a step that is the same or similar to that shown in FIG. 1C.

Refer to FIG. 4C, a recess 260 is formed by a step that is the same or similar to that shown in FIG. 1D. The recess 260 passes through the redistribution layer 220 and the insulating layer 210 in the second opening 200 and the insulating layer 130 to extend further into the adhesive layer 165, such that a subsequently formed protection layer 230 is in direct contact with cover plate 170. Next, the protection layer 230 is formed on the back surface 100b of the substrate 100 and in the second opening 200 and the recess 260. In some embodiments, a surface of the protection layer 230 away from the substrate 100 is flat. In some embodiments, the surface of the protection layer 230 away from the substrate 100 is uneven. For example, the surface of the protection layer 230 covering the first openings 190 and/or the second opening 200 may be a recessed surface.

Refer to FIG. 4D, a recess 270 and a notch 280 are formed by a step that is the same or similar to that shown in FIGS. 1F and 1G. The recess 270 passes through the second opening 200 and the recess 260 in the protection layer 230 and passes through the adhesive layer 165 to extend further into the cover plate 170. In some embodiments, the notch 280 is formed after the recess 270 is formed. In other embodiments, the recess 270 may be formed after the notch 280 is formed.

The recess 270 is formed by a laser drilling process, rather than a sawing process using a saw blade, so that the accuracy and precision for formation of the recess 270 can be increased, thereby preventing some layers (e.g., the redistribution layer 220, the insulating layer 210, the insulating layer 130, and the spacer layer 160) from damage due to the position shift of the recess 270. Also, the protection layer 230 that is used for protecting such layers can be prevented from being excessively removed, thereby ensuring that the side surfaces of such layers can be very well protected.

Afterwards, the cover plate 170 may be separated using a breaking cut technique in a step that is the same or similar to that shown in FIG. 1H, thereby forming individual chip packages, as shown in FIG. 4E.

According to some embodiments, the laser drilling process and the breaking cut technique are employed to replace the sawing process using a saw blade. Therefore, not only can the cutting shift problem be prevented, but the size of the scribe line is also not limited by the size of the saw blade (the width of the scribe line can be reduced to less than 80 μm, for example to 60 μm or less). Therefore, the design flexibility of the scribe line can be effectively increased. Moreover, the number of chip packages obtained by dicing a single wafer can be increased further. Furthermore, compared to the use of the saw blade, the required processing time for separating the wafer using the laser drilling process and the breaking cut technique is shorter and the process cost is lower. Therefore, manufacturing cost and manufacturing time can effectively be reduced.

It should be understood that the method for forming a chip package mentioned above is not limited to a chip package with an optical sensing device, and may be implemented for other chip package types. For example, the methods for forming the recess and the notch and the method for separating several chip packages may be implemented for the chip package with a device that is configured to sense biometrics (e.g., fingerprint recognition devices), a device that is configured to sense environmental characteristics (e.g., temperature-sensing element, humidity-sensing element, pressure-sensing element, capacitance-sensing element), or another suitable chip package.

While the invention has been disclosed in terms of the preferred embodiments, it is not limited. The various embodiments may be modified and combined by those skilled in the art without departing from the concept and scope of the invention.

What is claimed is:

1. A chip package, comprising:
a substrate having a front surface, a back surface, and a side surface;
a redistribution layer on the back surface and electrically connected to a sensing or device region in the substrate;
a protection layer covering the redistribution layer and extending onto the side surface; and
a cover plate on the front surface and laterally protruding from the protection layer on the side surface, wherein the cover plate has a first surface facing the front surface and a second surface facing away from the front surface, and a bottom portion of the cover plate broadens from the first surface towards the second surface.

2. The chip package as claimed in claim 1, wherein the bottom portion of the cover plate has a side surface adjacent to and tilted to the first surface.

3. The chip package as claimed in claim 1, wherein a top portion of the cover plate broadens from the second surface towards the first surface.

4. The chip package as claimed in claim 3, wherein the top portion of the cover plate has a side surface adjacent to and tilted to the second surface.

5. The chip package as claimed in claim 1, wherein the cover plate has a side surface adjacent to the bottom portion of the cover plate and substantially vertical to the first surface and/or the second surface.

6. The chip package as claimed in claim 1, wherein the protection layer on the back surface of the substrate has a flat side surface and an edge of the first surface of the cover plate is substantially aligned with the side surface of the protection layer.

7. The chip package as claimed in claim 1, wherein the bottom portion of the cover plate has a side surface surrounds the protection layer as viewed from the top.

8. The chip package as claimed in claim 1, wherein the redistribution layer further extends onto the side surface of the substrate and the protection layer covers an end of the redistribution layer on the side surface of the substrate.

9. The chip package as claimed in claim 1, further comprising an insulating layer between the substrate and the cover plate, wherein the insulating layer comprises a conductive pad therein and the conductive pad is electrically connected to the sensing or device region and the redistribution layer, and wherein the protection layer covers a side surface of the insulating layer.

10. The chip package as claimed in claim 1, further comprising a spacer layer or an adhesive layer between the substrate and the cover plate and having a side surface covered by the protection layer.

11. A method for forming a chip package, comprising:
providing a substrate, wherein the substrate has a front surface, a back surface, and a side surface;
forming a redistribution layer on the back surface, wherein the redistribution layer is electrically connected to a sensing or device region in the substrate;
forming a protection layer to cover the redistribution layer and extend onto the side surface; and
forming a cover plate on the front surface, wherein the cover plate laterally protrudes from the protection layer on the side surface, and wherein the cover plate has a first surface facing the front surface and a second surface facing away from the front surface, and a bottom portion of the cover plate broadens from the first surface towards the second surface.

12. The method as claimed in claim 11, wherein the redistribution layer further extends onto the side surface, and wherein the method for forming a chip package further comprises cutting the redistribution layer prior to formation of the protection layer, such that the redistribution layer on the side surface has an end that is covered by the protection layer.

13. The method as claimed in claim 11, further comprising forming a recess in the protection layer on the back surface and extending into the cover plate, such that the bottom portion of the cover plate broadens from the first surface towards the second surface.

14. The method as claimed in claimed in claim 13, wherein the step of forming the recess comprises performing a laser drilling process.

15. The method as claimed in claim 13, further comprising forming a spacer layer or an adhesive layer between the substrate and the cover plate prior to formation of the redistribution layer, wherein the recess extends through the spacer layer or the adhesive layer.

16. The method as claimed in claim 13, further comprising forming a notch in the cover plate, such that a top portion of the cover plate broadens from the second surface towards the first surface, wherein the notch is substantially aligned with the recess.

17. The method as claimed in claim 16, wherein the notch is formed by a scribing technique.

18. The method as claimed in claim 16, wherein the notch is formed after the formation of the recess.

19. The method as claimed in claim 16, further comprising cutting the cover plate using a breaking cut technique, such that the cover plate is cut off along the recess and the notch.

20. The method as claimed in claim 19, wherein the cover plate is substantially and vertically cut off along the recess and the notch.
